(19) United States
(12) Patent Application Publication
(10) Pub. No.: US 2008/0246051 A1
(43) Pub. Date: Oct. 9, 2008

(54) LIGHT EMITTING APPARATUS AND METHOD FOR MANUFACTURING SAME

(75) Inventors: Tadaaki Hosokawa, Kanagawa-ken (JP); Osamu Horiuchi, Kanagawa-ken (JP); Takayuki Matsuyama, Kanagawa-ken (JP); Makoto Okada, Chiba-ken (JP)

Correspondence Address: AMIN, TUROCY & CALVIN, LLP, 1900 EAST 9TH STREET, NATIONAL CITY CENTER, 24TH FLOOR,, CLEVELAND, OH, 44114, US

(73) Assignee: KABUSHIKI KAISHA TOSHIBA, Tokyo (JP)

(21) Appl. No.: 12/062,714

(22) Filed: Apr. 4, 2008

(30) Foreign Application Priority Data
Apr. 6, 2007 (JP) 2007-100100

(51) Int. Cl. H01L 33/00

(52) U.S. Cl. 257/99; 438/26; 257/E33.063; 257/E33.057

(57) ABSTRACT

A light emitting apparatus includes: a light emitting element including a laminated body, an electrode provided on the laminated body, and a pad electrode provided on the electrode, the laminated body including a semiconductor light emitting layer; a mounting member having a metal bonding layer; and an alloy solder containing gold for bonding the pad electrode to the metal bonding layer. The pad electrode has at least a first gold layer provided on the electrode and being thicker than the electrode and a first metal barrier layer provided on the first gold layer, and the melting point of the alloy solder is lower than the melting point of alloys with elements constituting the first metal barrier layer and the alloy solder.

### CROSS-REFERENCE TO RELATED APPLICATIONS

This application is based upon and claims the benefit of priority from the prior Japanese Patent Application No. 2007-100100, filed on Apr. 6, 2007; the entire contents of which are incorporated herein by reference.

### BACKGROUND OF THE INVENTION

1. Field of the Invention

This invention relates to a light emitting apparatus and a method for manufacturing the same

2. Background Art

The junction-down structure of a light emitting apparatus such as a semiconductor laser and an LED (light emitting diode), in which structure the light emitting layer side is located close to the heat sink, is superior in heat dissipation. In this structure, an electrode provided on the semiconductor laminated body including the light emitting layer is bonded to the metal bonding layer of the mounting member with an alloy solder, for example.

A light emitting apparatus may be subjected to stress due to temperature increase and decrease during the assembling process, and the stress may remain after completion of the assembling process. Mechanical stress including impacts may also be applied thereto. Such stress may cause characteristics variation and reliability degradation of the light emitting apparatus, and hence is desirably reduced.

U.S. Pat. No. 6,804,276 discloses a semiconductor laser apparatus in which a semiconductor laser device, an insulative submount for reducing stress, a metal heat sink, and other members are stacked.

### SUMMARY OF THE INVENTION

According to an aspect of the invention, there is provided a light emitting apparatus including: a light emitting element including a laminated body, an electrode provided on the laminated body, and a pad electrode provided on the electrode, the laminated body including a semiconductor light emitting layer; a mounting member having a metal bonding layer; and an alloy solder containing gold for bonding the pad electrode to the metal bonding layer, the pad electrode having at least a first gold layer provided on the electrode and being thicker than the electrode and a first metal barrier layer provided on the first gold layer, and the melting point of the alloy solder being lower than the melting point of alloys with elements constituting the first metal barrier layer and the alloy solder.

According to another aspect of the invention, there is provided a method for manufacturing a light emitting apparatus, including: forming a pad electrode in which a first gold layer, a first metal barrier layer, and a first surface protection layer containing gold are laminated in this order on an electrode provided on a laminated body including a semiconductor light emitting layer; and melting an alloy solder containing gold interposed between the first surface protection layer and a metal bonding layer constituting an upper surface of a mounting member to bond the pad electrode to the metal bonding layer.

### BRIEF DESCRIPTION OF THE DRAWINGS

FIGS. 1A and 1B are schematic views showing a light emitting apparatus according to a first embodiment;

FIG. 2 is a phase diagram for the alloy solder;

FIGS. 3A and 3B are schematic views showing a light emitting apparatus according to a second embodiment;

FIGS. 4A and 4B are schematic views showing a modification of the second embodiment;

FIG. 5 is a flow chart illustrating a bonding process of the modification in FIGS. 4A and 4B; and

FIGS. 6A and 6B are schematic views showing a process for bonding the alloy solder.

### DETAILED DESCRIPTION OF THE INVENTION

Embodiments of the invention will now be described with reference to the drawings.

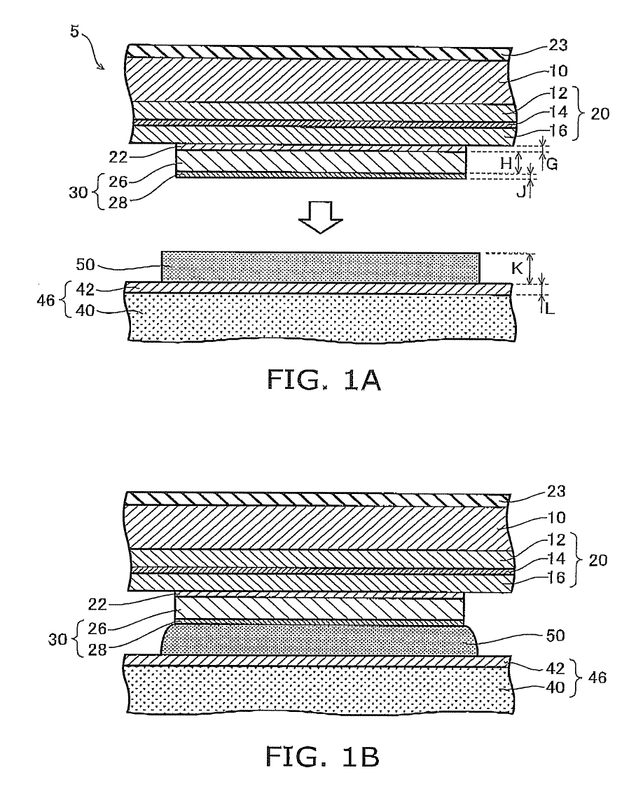

FIG. 1 shows a light emitting apparatus according to a first embodiment of the invention. As shown in FIG. 1A, a laminated body 20 including an n-type layer 12, a light emitting layer 14, and a p-type layer 16 is formed on a semiconductor substrate 10 by MOCVD (metal organic chemical vapor deposition), for example.

Subsequently, an ohmic electrode 22 in ohmic contact with the laminated body 20 is formed on the laminated body 20. Furthermore, the ohmic electrode 22 is covered with a pad electrode 30, which includes a gold layer 26 thicker than the ohmic electrode 22 and a metal barrier layer 28 provided thereon. An n-side electrode 23 is formed on the substrate 10. Thus the light emitting element 5 is completed.

The metal constituting the ohmic electrode 22 in contact with the p-type layer 16 can be Ti (titanium) to decrease contact resistance. The ohmic electrode 22 (thickness G) is preferably composed of Ti/Pt (platinum), Ti/Pt/Au (gold), Ti/Mo (molybdenum), or Ti/Mo/Au. The thickness G is preferably e.g. 0.3 to 1 μm.

The pad electrode 30 is provided to cover the ohmic electrode 22. The pad electrode 30 includes at least the gold layer 26 (thickness H) and the metal barrier layer 28 (thickness J). The gold layer 26 is highly ductile and malleable, allowing reduction of stress between the light emitting element 5 and the mounting member 46. To this end, the thickness H of the gold layer 26 is preferably greater than the thickness G of the ohmic electrode 22, and is illustratively 1 to 5 μm. Such a thick gold layer 26 can be easily formed by plating. The metal barrier layer 28 provided on the gold layer 26 is made of a single metal such as Pt, Mo, or W, or a multilayer film thereof or an alloy thereof. The thickness 3 may be smaller than the thickness G, and is illustratively 0.05 to 0.5 μm.

On the other hand, a metal bonding layer 42 (thickness L) is provided on a submount member 40 to constitute a mounting member 46. A conductive layer of Ti or the like can be provided between the metal bonding layer 42 and the submount member 40 to improve contact therebetween. The metal bonding layer 42 may be provided on a lead to constitute a package or other mounting member (not shown).

An alloy solder 50 interposed between the pad electrode 30 and the metal bonding layer 42 is melted to bond them together. The alloy solder 50 can illustratively be a gold-containing alloy.

The gold-containing alloy solder 50 (thickness K) can illustratively be AuSn (gold-tin), AuSi (gold-silicon), or AuGe (gold-germanium). The melting point of this eutectic alloy depends on its composition and is expressed by a phase diagram. The thickness K of the alloy solder 50 is illustratively 0.5 to 5 μm. Alternatively, the alloy solder 50 can be SnAgCu, for example. On the other hand, because the stress is reduced by the gold layer 26, the thickness L of the metal bonding layer 42 may be smaller than the thickness H of the gold layer 26, and is illustratively 0.3 to 1.0 μm. The metal bonding layer 42 does not need to contain gold, but the bonding can be made more secure by using gold.

FIG. 1B is a schematic cross-sectional view showing the light emitting element 5 and the metal bonding layer 42 bonded together by pressurizing thereof and melting of the alloy solder 50. The melting point of the alloy solder 50 is set to be lower than the melting point of alloys with elements constituting the metal barrier layer 28 and the alloy solder 50. Thus the alloy solder 50 is melted to bond the pad electrode 30 to the metal bonding layer 42. Here, the melting point of the alloy solder 50 is lower than the melting point of alloys with elements constituting the metal barrier layer 28 and the alloy solder 50, preventing the alloy solder 50 from being alloyed with the gold layer 26. The elements constituting the metal barrier layer 28 and the alloy solder 50 do not need to substantially form an alloy.

If the metal bonding layer 42 contains gold, the composition of the alloy solder 50 varies. However, the thickness L of the metal bonding layer 42 is smaller than the thickness H of the gold layer 26. Hence the effect of the variation in the alloy composition can be reduced relative to the case where the gold layer 26 is alloyed. Although gold in the metal bonding layer 42 is alloyed with the alloy solder 50 also in this case, alloying between the gold layer 26 and the alloy solder 50 can be prevented by the metal barrier layer 28.

As shown in FIG. 1B, the metal barrier layer 28 prevents the gold layer 26 from melting into the alloy solder 50. The gold layer 26 serves to reduce the stress applied to the laminated body 20 including the light emitting layer 14. Thus the characteristics variation of the light emitting element 5 due to dislocation and other degradation of crystallinity can be prevented, allowing higher reliability. The thermal conductivity (0° C.) of gold is 236 W/(m·K), which is higher than 68 W/(m·K) for Sn (tin), 177 W/(m·K) for W (tungsten), 72 W/(m·K) for Pt, 139 W/(m·K) for Mo, and 57 W/(m-K) for Au₈₀Sn₂₀. Hence the heat dissipation is improved, and the long-term reliability in the energized condition is further improved.

Here, a description is given of the variation of the melting point for the alloy solder 50 of AuSn.

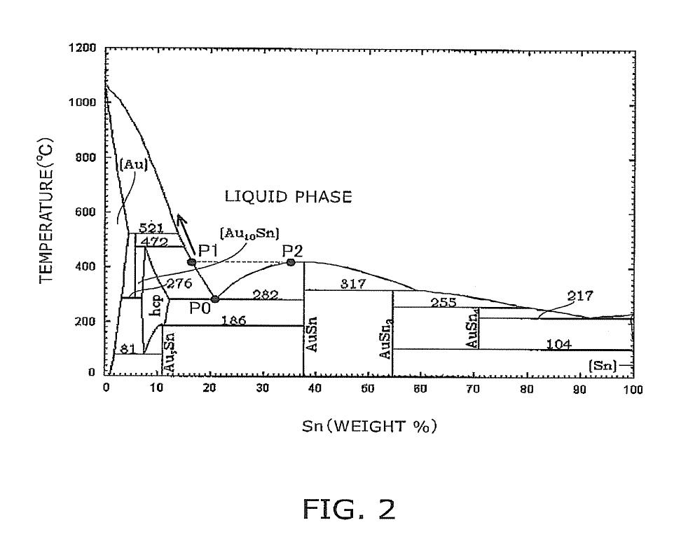

FIG. 2 shows a phase diagram for the AuSn alloy, where the vertical axis represents temperature, and the horizontal axis represents Sn weight %. At point P0 with a weight composition of approximately 80% Au and approximately 20% Sn, the melting point of the alloy is minimized to approximately 282° C., That is, the melting point increases as the Sn weight % deviates from point P0 to either the larger or smaller side.

If the metal barrier layer 28 is not provided, the thick gold layer 26 is melted into the alloy solder 50, and the gold weight % increases, that is, moves to the left of point P1 in FIG. 2 (in the direction of the arrow), resulting in the melting point higher than 420° C. A high mounting temperature increases thermal stress due to difference in linear expansion coefficient associated with temperature increase and decrease, and may degrade the characteristics and reliability of the light emitting apparatus. Hence the melting point is preferably set to 420° C. or less. Furthermore, a high mounting temperature prolongs the temperature increasing and decreasing time in the assembling apparatus and degrades the productivity.

On the other hand, the melting point is locally maximized to approximately 420° C. at point P2, which is located in the vicinity of approximately 35 weight % Sn. If the Sn composition is higher than this, the melting point decreases, but the decrease of bonding strength and oxidation of the alloy solder 50 may occur.

For these reasons, the Sn weight % in the composition is preferably restricted to within the variation range from 15 weight % at point. P1 to 35 weight % at point P2. In this embodiment, in the case where the metal bonding layer 42 contains gold, because of its small thickness, Sn is easily restricted to within the range of 15 to 35 weight % even if gold is alloyed. That is, the preset temperature can be decreased to 420° C. or less, and the temperature range can be narrowed, allowing reduction of thermal stress and enhancement of productivity in the mounting process. While the foregoing description is made with reference to AuSn, it is also possible to use alloy solders such as AuGe and AuSi.

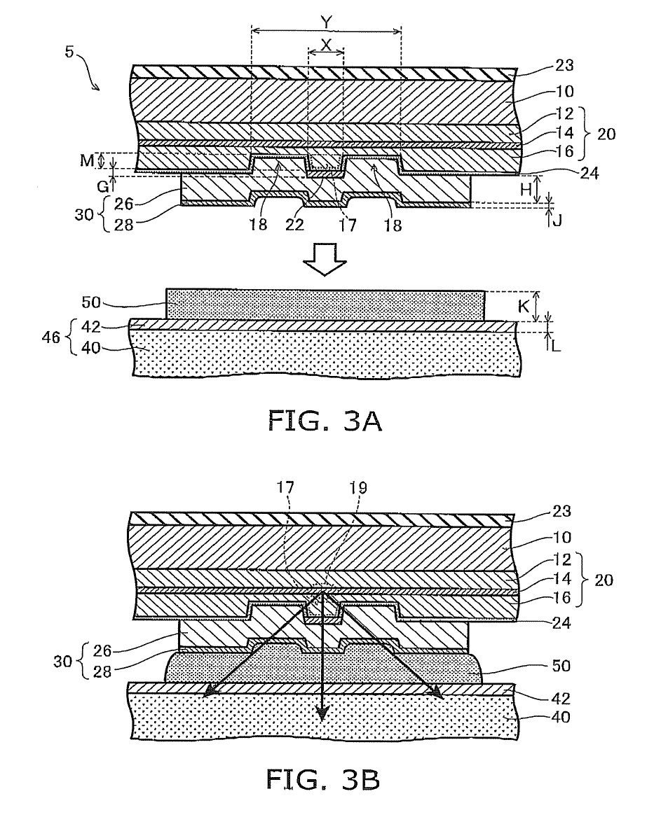

FIG. 3 is a schematic view showing a light emitting apparatus according to a second embodiment. While a nitride semiconductor laser apparatus is described in this embodiment, the material is not limited to nitrides, but other materials may also be used. The term “nitride semiconductor” used herein refers to a semiconductor represented by (AlₓB₁₋ₓ)_{y}Ga_{z}In_{1-y-z}N (0≦x≦1, 0≦y≦1, 0≦z≦1, y+z≦1), and also encompasses those containing As and/or P as group V elements and those containing p-type or n-type impurities.

The substrate 10 is made of n-type GaN. As shown in FIG. 3, the p-type layer 16 of the laminated body 20 made of a nitride semiconductor has a ridge waveguide 17 (width X and height M) and grooves 18 (width Y) on both sides thereof. An insulating film 24 illustratively made of SiO₂ is formed outside the upper portion of the ridge waveguide 17 constituting an optical resonator A p-side electrode to serve as an ohmic electrode 22 (thickness G) is formed on top of the ridge waveguide 17. Here, each of the thicknesses G, H, and J takes the same range as that in the first embodiment.

The height M is 1 μm or less, the width X is 1 to 2 μm, and the width Y is 5 to 30 μm. The pad electrode 30 is provided to cover the two grooves 18. In the case of a semiconductor laser apparatus, in the light emitting layer 14, the light emitting region 19 subjected to waveguiding by the ridge waveguide 17 is the main source of heat generation. A conductive layer of Ti or the like can be provided between the insulating film 24 and the gold layer 26 to improve contact therebetween.

In the second embodiment, stress including thermal stress is reduced in the vicinity of the ridge waveguide 17 and the light emitting region 19 of the laminated body 20, improving reliability. In particular, nitride materials have high Young's modulus and small plastic deformation, and therefore stress tends to concentrate inside. Hence, stress is easily reduced, for example, by Interposing gold having a Young's modulus of 7.8×10¹⁰ N/m² between GaN having 2.9×10¹¹ N/m² and AlN (submount member) having 2.7×10¹¹ N/m². The groove 18 has generally the same height as the ridge waveguide 17. However, as shown in FIG. 3B, the recess in the surface of the pad electrode 30 is filled with the melted alloy solder 50, and hence good heat dissipation can be maintained.

Furthermore, the outside of the groove 18 of the laminated body 20 has generally the same height as the ridge waveguide 17 to avoid concentration of stress on the ridge waveguide 17, allowing prevention of damage due to mechanical impacts to the ridge waveguide 17. Heat generated in the vicinity of the light emitting region 19 is dissipated outside through the gold layer 26, the alloy solder 50, and the mounting member 46 in the direction of the arrows, improving heat dissipation.

Furthermore, abnormal growth tends to occur on the surface of the laminated body 20 of a nitride semiconductor formed by crystal growth on the substrate 10, and a protrusion having a height of 1 μm or more may be formed. However, by forming a thick gold layer 26, this protrusion can be prevented from being in contact with the metal bonding layer 42 of the mounting member 46.

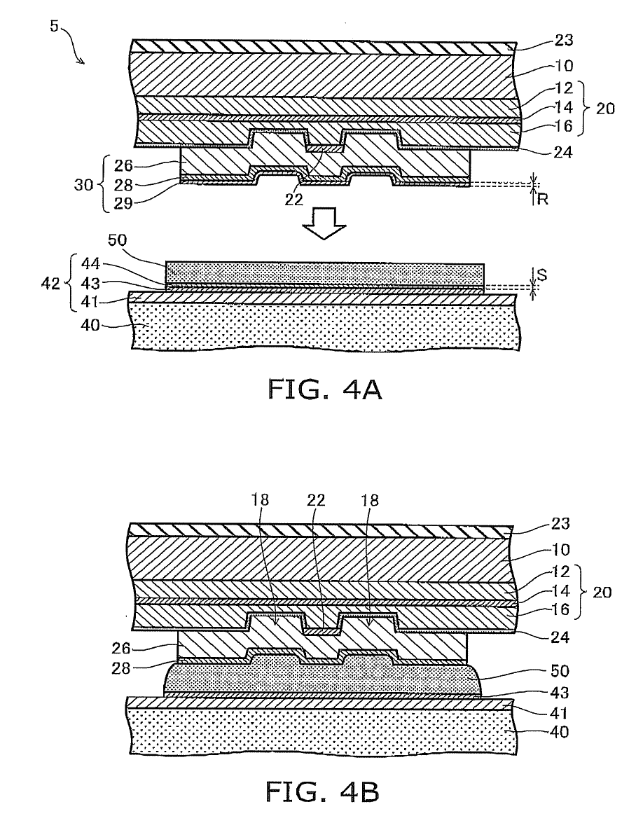

FIG. 4 is a schematic cross-sectional view of a light emitting apparatus according to a modification of the second embodiment. In this modification, as shown in FIG. 4A, a surface protection layer 29 (having a thickness R of e.g. 0.05 to 0.2 μm) of gold or the like is provided on the metal barrier layer 28 of the pad electrode 30. The thickness R may be smaller than the thickness J of the metal barrier layer 28. The thin gold layer of the surface protection layer 29 is alloyed with the alloy solder 50 to slightly increase the gold weight %. However, its melting point is lower than the melting point of alloys with elements constituting the metal barrier layer 28 and the alloy solder 50, preventing the gold layer 26 from being alloyed.

FIG. 4B is a schematic cross-sectional view of the light emitting apparatus in which the alloy solder 50 on the metal bonding layer 42 is melted to bond the pad electrode 30 to the metal bonding layer 42. The melted alloy solder 50 is solidified in contact with the metal barrier layer 28 and the metal bonding layer 42. However, between the alloy solder 50 and the metal barrier layer 28, the surface protection layer 29 may partly remain without being alloyed.

Furthermore, as shown in FIG. 4A, the metal bonding layer 42 may be made of a gold layer 41, a second metal barrier layer 43, and a surface protection layer 44 (having a thickness S of e.g. 0.05 to 0.2 μm) of gold or the like laminated in this order, and the alloy solder layer 50 may be formed on the surface protection layer 44. In this case, the materials of the metal barrier layers 28 and 43 may be either identical or different.

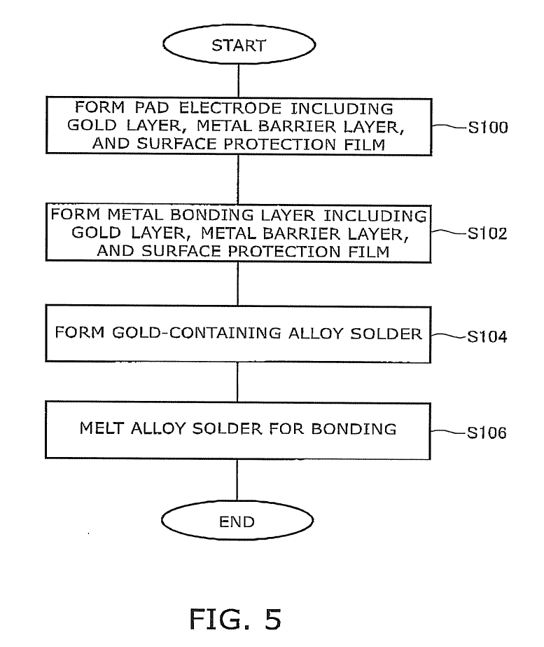

FIG. 5 is a flow chart illustrating a bonding process of the modification of the second embodiment in which the pad electrode 30 and the metal bonding layer 42 include the barrier layers 28, 43 and the surface protection layers 29, 44. A pad electrode 30 including a gold layer 26, a metal barrier layer 28, and a surface protection layer 29 is formed to cover the ohmic electrode 22 and the bottom of the grooves 18 (step S100). On the other hand, a metal bonding layer 42 including a gold layer 41, a metal barrier layer 43, and a surface protection layer 44 is laminated on the submount member 40 to form a mounting member 46 (step S102).

Subsequently, a gold-containing alloy solder 50 is formed on at least one of the surface protection layers 29 and 44 (step S104). The alloy solder 50 is melted under pressurization to bond the pad electrode 30 to the metal bonding layer 42 (step S106).

In this modification, the surface protection layers 29, 44 of gold or the like are provided on the metal barrier layers 28, 43 to improve wettability with the alloy solder 50, facilitating the bonding. In this case, more preferably, the metal barrier layers 28, 43 and the surface protection layers 29, 44 are continuously formed in the same vacuum chamber. In the case where the surface protection layers 29, 44 are made of gold, the composition of the alloy solder 50 varies after melting. However, if their thicknesses R, S are smaller than the thickness of the alloy solder 50, the range of composition variation can be narrowed. Thus the melting point can be easily restricted to within the range between point P1 and point P2, allowing a stabler bonding process and high productivity.

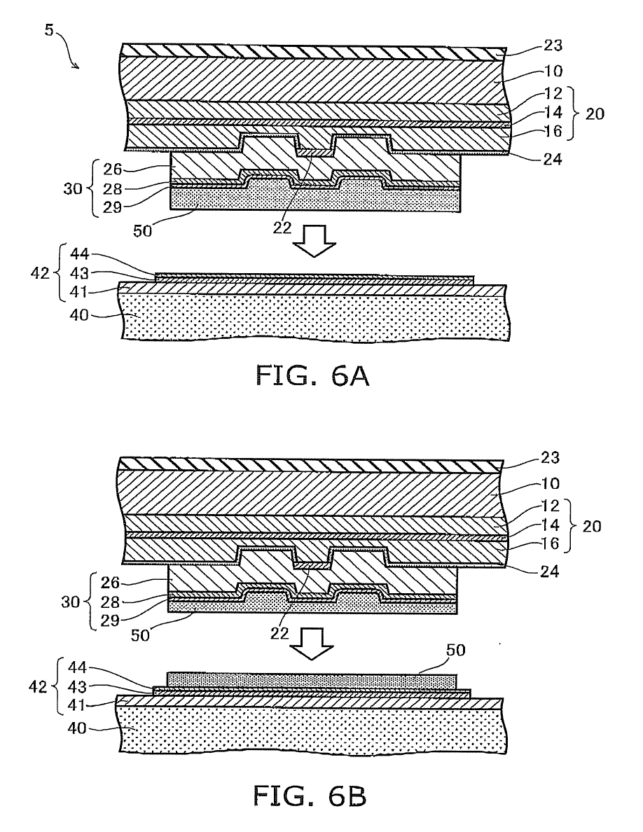

FIG. 6 shows a process for bonding the alloy solder 50. In FIGS. 1A, 3A, and 4A, the alloy solder 50 is formed only on the metal bonding layer 42. However, the alloy solder 50 may be formed on the pad electrode 30. In FIG. 6A, the alloy solder 50 is formed on the pad electrode 30 of the light emitting element 5. In this case, the step of forming the pad electrode 30 can be continuously followed by forming the alloy solder 50 by vapor deposition or plating, allowing simplification of the process. In FIG. 6B, the alloy solder 50 is formed on both the pad electrode 30 and the metal bonding layer 42. In this case, the bonding strength can be generally equalized on the pad electrode 30 and the metal bonding layer 42.

According to the first and second embodiment and the associated modification, by using a pad electrode 30 including a gold layer 26 that can be kept without being alloyed with the alloy solder 50, a light emitting apparatus with reduced stress and improved reliability is provided. Furthermore, a method for manufacturing a light emitting apparatus with a stable composition of the alloy solder 50 and high productivity is provided.

The embodiments of the invention have been described with reference to the drawings. However, the invention is not limited to these embodiments. The laminated body, ohmic electrode, pad electrode, metal barrier layer, surface protection layer, metal bonding layer, alloy solder, and mounting member constituting the invention can be modified by those skilled in the art without departing from the spirit of the invention, and such modifications are also encompassed within the scope of the invention.

1. A light emitting apparatus comprising:
a light emitting element including a laminated body, an electrode provided on the laminated body, and a pad electrode provided on the electrode, the laminated body including a semiconductor light emitting layer;
a mounting member having a metal bonding layer; and
an alloy solder containing gold for bonding the pad electrode to the metal bonding layer,
the pad electrode having at least a first gold layer provided on the electrode and being thicker than the electrode and a first metal barrier layer provided on the first gold layer, and
the melting point of the alloy solder being lower than the melting point of alloys with elements constituting the first metal barrier layer and the alloy solder.

2. The light emitting apparatus according to claim 1, further comprising:
a first surface protection layer containing gold provided on the first metal barrier layer.

3. The light emitting apparatus according to claim 1, wherein the metal bonding layer is made of a second gold layer.

4. The light emitting apparatus according to claim 2, wherein
the metal bonding layer has a second gold layer and a second metal barrier layer,
the melting point of the alloy solder is lower than the melting point of alloys with elements constituting the second metal barrier layer and the alloy solder, and
the second metal barrier layer side is bonded to the alloy solder.

5. The light emitting apparatus according to claim 4, wherein the first metal barrier layer and the second metal barrier layer contain a same element.

6. The light emitting apparatus according to claim 4, further comprising a second surface protection layer containing gold provided on the second metal barrier layer.

7. The light emitting apparatus according to claim 1, wherein the alloy solder is made of one of AuSn, AuGe and AuSi.

8. The light emitting apparatus according to claim 7, wherein the alloy solder is made of AuSn which includes Sn in the range of 15 to 35 weight %.

9. The light emitting apparatus according to claim 1, wherein
the light emitting element has a ridge waveguide constituting an optical resonator on an upper surface of the laminated body, and
a laser light is emitted from the semiconductor light emitting layer by injecting a current from the electrode formed on top of the ridge waveguide.

10. The light emitting apparatus according to claim 9, further comprising a first surface protection layer containing gold provided on the first metal barrier layer.

11. The light emitting apparatus according to claim 10, wherein
the metal bonding layer has a second gold layer and a second metal barrier layer,
the melting point of the alloy solder is lower than a melting point of alloys with elements constituting the second metal barrier layer and the alloy solder, and
a side of the second metal barrier layer is bonded to the alloy solder.

12. The light emitting apparatus according to claim 11, wherein the first metal barrier layer and the second metal barrier layer contain a same element.

13. The light emitting apparatus according to claim 11, further comprising a second surface protection layer containing gold provided on the second metal barrier layer.

14. The light emitting apparatus according to claim 9, wherein the alloy solder is made of one of AuSn, AuGe and AuSi.

15. The light emitting apparatus according to claim 14, wherein the alloy solder is made of AuSn which includes Sn in the range of 15 to 35 weight %.

16. A method for manufacturing a light emitting apparatus, comprising:
forming a pad electrode in which a first gold layer; a first metal barrier layer, and a first surface protection layer containing gold are laminated in this order on an electrode provided on a laminated body including a semiconductor light emitting layer; and
melting an alloy solder containing gold interposed between the first surface protection layer and a metal bonding layer constituting an upper surface of a mounting member to bond the pad electrode to the metal bonding layer.

17. The method for manufacturing a light emitting apparatus according to claim 16, further comprising forming the metal bonding layer including a second gold layer, a second metal barrier layer, and a second surface protection layer containing gold laminated in this order on a submount member.

18. The method for manufacturing a light emitting apparatus according to claim 17, wherein the alloy solder is formed on one of the first surface protection layer and the metal bonding layer, and is thereafter melted.

19. The method for manufacturing a light emitting apparatus according to claim 17, wherein the alloy solder is formed on both the first surface protection layer and the metal bonding layer, and is thereafter melted.

20. The method for manufacturing a light emitting apparatus according to claim 16, wherein one of AuSn, AuGe, AuSi is used for the alloy solder.
